(19) United States
(12) Patent Application Publication
(10) Pub. No.: US 2004/0207085 A1
(43) Pub. Date: Oct. 21, 2004

(54) Semiconductor device and method of manufacturing the same

(75) Inventors: Yasuhisa Fujii, Hyogo (JP); Takao Kamoshima, Hyogo (JP); Takeru Matsuoka, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/787,317

(22) Filed: Feb. 27, 2004

(30) Foreign Application Priority Data
Apr. 17, 2003 (JP) 2003-112947(P)

(51) Int. Cl. H01L 23/48

(52) U.S. Cl. 257/751; 257/758

(57) ABSTRACT

A method of manufacturing a semiconductor device includes the steps of forming a copper layer by plating, forming a defect trapping film on the copper layer, moving a defect in the copper layer into the defect trapping film by annealing or the like, and removing the defect trapping film. Thereby, a semiconductor device in which concentration of micro-voids in a portion in proximity to a bottom of a via due to stress migration can be restrained and a method of manufacturing the same can be obtained.

### BACKGROUND OF THE INVENTION

1. Field of the Invention

The present invention relates to a semiconductor device and a method of manufacturing the same. In particular, the invention relates to a semiconductor device having a copper interconnection structure and a method of manufacturing the same.

2. Description of the Background Art

In an integrated circuit of a conventional semiconductor device, an aluminum (Al) alloy is mainly used for a metal interconnection. However, as microfabrication of a semiconductor device progresses, interconnections have been microfabricated and provided in the form of more layers, and a space between the interconnections has been reduced. Although interconnection delay time becomes shorter as the product (RC) obtained by multiplying resistance (R) of an interconnection by capacitance (C) between interconnections becomes smaller, capacitance (C) between interconnections in a lateral direction increases due to microfabrication. Thus, copper (Cu) interconnections having lower resistance have been used in most-advanced devices.

A semiconductor device having such a copper interconnection is disclosed, for example, in “Stress-Induced Voiding Under Vias Connected To Wide Cu Metal Leads” by E. T. Ogawa et al., IEEE 02CH37320 40th Annual International Reliability Physics Symposium, Dallas, Tex., 2002, pp. 312-321.

In a flow of manufacturing a semiconductor device having such a copper interconnection, methods such as a dual damascene method and a single damascene method are used. In the dual damascene method, after a via and a trench at an interconnection portion are formed by dry etching, a barrier metal and a seed copper film are deposited, and electrolytic plating is performed to deposit a copper film. Then, thermal treatment is applied to stabilize film quality of the copper film, and CMP (Chemical Mechanical Polishing) is performed to polish and remove the copper film so as to be left only within the via and the trench, forming a copper interconnection.

On the other hand, in the single damascene method, after a via is opened, a barrier metal and a seed copper film are deposited, and electrolytic plating is performed to deposit a copper film. Then, thermal treatment is applied to stabilize film quality of the copper film, and CMP is performed to fill only the via with the copper film. Thereafter, an interlayer insulating layer is deposited, and an interconnection trench is formed by photolithography and dry etching. A barrier metal and a seed copper film are deposited, and electrolytic plating is performed to deposit a copper film. After thermal treatment is applied to stabilize film quality of the copper film, CMP is performed to fill only the interconnection trench with the copper film.

Although copper plating is generally used in the foregoing two methods, it is known that a copper plating film includes a number of micro-voids within the film. In addition, it is believed that, when a stress migration test is conducted, due to stress distribution caused in a portion in proximity to a bottom of a via, the forgoing micro-voids diffuse within the film and concentrate in the portion in proximity to the bottom of the via. When such concentration of the micro-voids occurs in the portion in proximity to the bottom of the via due to heat stress, there arises a possibility of increased interconnection resistance and occurrence of a break in the foregoing portion.

### SUMMARY OF THE INVENTION

The present invention is made to solve the aforementioned problem. An object of the present invention is to provide a semiconductor device in which concentration of micro-voids in a portion in proximity to a bottom of a via due to stress migration can be restrained, and a method of manufacturing the same.

A semiconductor device of the present invention includes a first copper layer, an insulating layer, a second copper layer, and a barrier layer. The insulating layer is formed on the first copper layer, and has a via reaching the first copper layer. The second copper layer is electrically connected to the first copper layer through the via. The barrier layer is located between the second copper layer and the insulating layer, and between the first copper layer and the second copper layer. The barrier layer has a structure in which a tantalum nitride layer is sandwiched by layers having a better adhesive property to copper than the tantalum nitride layer.

According to the semiconductor device of the present invention, the barrier layer located between the second copper layer and the insulating layer has the tantalum nitride layer, copper in the second copper layer can effectively be prevented from diffusing into the insulating layer. In addition, since the tantalum nitride layer of the barrier layer contacts neither the first copper layer nor the second copper layer, bonding of copper and tantalum nitride, which is a structure having a weak adhesion property and a high rate of occurrence of voids, can be prevented. Therefore, concentration of micro-voids in proximity to a contact portion between the first copper layer and the barrier layer and in proximity to a contact portion between the second copper layer and the barrier layer due to heat stress can be restrained.

Another semiconductor device of the present invention includes a first copper layer, an insulating layer, and a second copper layer. The insulating layer is formed on the first copper layer, and has a via reaching the first copper layer. The second copper layer is electrically connected to the first copper layer through the via. At least either one of the first and second copper layers contains an inert element.

According to another semiconductor device of the present invention, since at least either one of the first and second copper layers contains an inert element, at least either one of the first and second copper layers is once caused to be amorphous, and then caused to be crystalline by annealing. Copper has better fluidity in an amorphous state than in a crystalline state. Thus, when annealing is performed under the same condition, growth of copper crystal grains can be promoted and vacancies can be reduced more in an amorphous state than in a crystalline state. Further, since the size of copper crystal grains can be increased by the promotion of growth of the copper crystal grains, boundaries between the crystal grains (triple points) in which voids are apt to occur can be reduced, and an interval between the triple points can be increased. Thereby, voids in at least either one of the first and second copper layers can be retrained from moving. Therefore, concentration of micro-voids in a portion in proximity to a bottom of the via due to heat stress can be restrained.

Still another semiconductor device of the present invention includes a first copper layer, an insulating layer, and a second copper layer. The insulating layer is formed on the first copper layer, and has a via reaching the first copper layer. The second copper layer is electrically connected to the first copper layer through the via. At least either one of the first and second copper layers contains an element in group 8 of the periodic table.

According to still another semiconductor device of the present invention, an element in group 8 is introduced into at least either one of the first and second copper layers. The diffusion coefficient of an element in group 8 is greater than that of copper. Since a greater diffusion coefficient results in a higher probability of contacting vacancies, vacancies can effectively be filled with an element in group 8. Therefore, concentration of micro-voids in the portion in proximity to the bottom of the via due to heat stress can be restrained.

A method of manufacturing a semiconductor device of the present invention includes the steps of forming a copper layer by plating, forming a defect trapping film on the copper layer, moving a defect in the copper layer into the defect trapping film, and removing the defect trapping film.

According to the method of manufacturing a semiconductor device of the present invention, the density of defects such as, micro-voids in the copper layer can be reduced by the defect trapping film. Thus, concentration of micro-voids due to heat stress can be restrained.

Another method of manufacturing a semiconductor device of the present invention includes the steps of forming a copper layer by plating, implanting an inert element into the copper layer to make at least part of the copper layer amorphous, and heating the at least partially amorphous copper layer to crystallize an amorphous portion of the copper layer.

According to another method of manufacturing a semiconductor device of the present invention, since at least either one of the first and second copper layers contains an inert element, at least either one of the first and second copper layers is once caused to be amorphous, and then caused to be crystalline by annealing. Copper has better fluidity in an amorphous state than in a crystalline state. Thus, when annealing is performed under the same condition, growth of copper crystal grains can be promoted and vacancies can be reduced more in an amorphous state than in a crystalline state. Further, since the size of copper crystal grains can be increased by the promotion of growth of the copper crystal grains, boundaries between the crystal grains (triple points) in which voids are apt to occur can be reduced, and an interval between the triple points can be increased. Thereby, voids in at least either one of the first and second copper layers can be retrained from moving. Therefore, concentration of micro-voids in the portion in proximity to the bottom of the via due to heat stress can be restrained.

Still another method of manufacturing a semiconductor device of the present invention is a method of manufacturing a semiconductor device having an lower copper layer and an upper copper layer electrically connected through a via formed in an insulating layer, wherein at least one of the lower copper layer and the upper copper layer is formed by plating so as to contain an element in group 8 of the periodic table from when the layer is deposited by the plating.

Still another method of manufacturing a semiconductor device of the present invention is a method of manufacturing a semiconductor device having an lower copper layer and an upper copper layer electrically connected through a via formed in an insulating layer, wherein at least one of the lower copper layer and the upper copper layer is formed by plating, and has an element in group 8 of the periodic table introduced after the layer is deposited by the plating.

According to foregoing two still another methods of manufacturing a semiconductor device of the present invention, an element in group 8 is introduced into at least either one of the first and second copper layers. The diffusion coefficient of the element in group 8 is greater than that of copper. Since a greater diffusion coefficient results in a higher probability of contacting vacancies, vacancies can effectively be filled with an element in group 8. Therefore, concentration of micro-voids in the portion in proximity to the bottom of the via due to heat stress can be restrained.

Still another method of manufacturing a semiconductor device of the present invention includes the steps of forming an insulating layer having a concave portion on a main surface, forming a copper layer so as to fill the concave portion and cover the main surface of the insulating layer, removing the copper layer so as to be left within the concave portion, and performing thermal treatment for stabilizing film quality of the copper layer after removing the copper layer.

According to still another method of manufacturing a semiconductor device of the present invention, thermal treatment for stabilizing film quality is provided after the copper layer is polished and partially removed. Thus, heat conduction efficiency of the copper layer during thermal treatment is improved, because the copper layer has a lower volume by being polished and partially removed, compared with the case that thermal treatment is provided before the copper layer is polished and partially removed. Thereby, a portion in proximity to the bottom of the via in the copper layer can efficiently be heated, allowing effective and efficient stabilization of the film quality of the portion. In addition, since the volume of the copper layer is reduced by the polishing and partial removal, an absolute number of vacancies in the copper layer can also be decreased by the amount of the reduced volume.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing a structure of a semiconductor device in accordance with a first embodiment of the present invention.

FIG. 2 is a schematic cross sectional view showing a first step of a method of manufacturing the semiconductor device in the first embodiment of the present invention.

FIG. 3 is a schematic cross sectional view showing a second step of the method of manufacturing the semiconductor device in the first embodiment of the present invention.

FIG. 4 is a schematic cross sectional view showing another method of manufacturing the semiconductor device in the first embodiment of the present invention.

FIG. 5 is a schematic cross sectional view showing a method of manufacturing a semiconductor device in accordance with a second embodiment of the present invention.

FIG. 6 is a schematic cross sectional view showing a structure of a semiconductor device in accordance with a third embodiment of the present invention, showing an enlarged view of a region P in FIG. 1.

FIG. 7 is a schematic cross sectional view showing a method of manufacturing a semiconductor device in accordance with a fourth embodiment of the present invention.

FIG. 8 is a schematic cross sectional view showing a method of manufacturing a semiconductor device in accordance with a fifth embodiment of the present invention.

### DESCRIPTION OF THE PREFERRED EMBODIMENTS

In the following, embodiments of the present invention will be described with reference to the drawings.

### First Embodiment

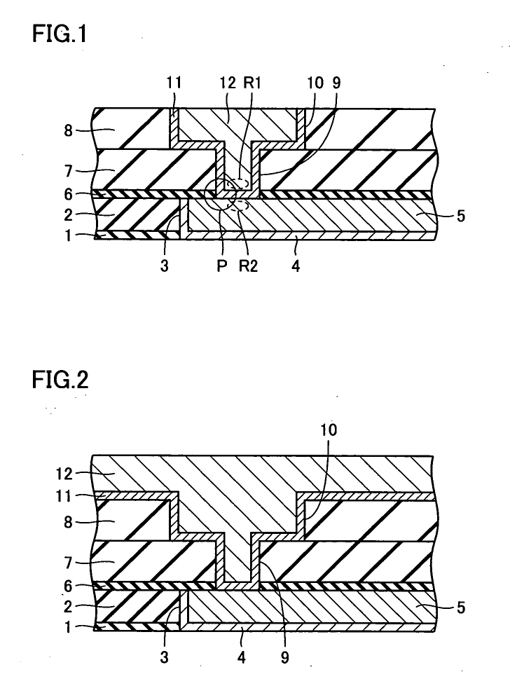

With reference to FIG. 1, an insulating layer 1 made of, for example, a silicon nitride film, and an interlayer insulating layer 2 made of, for example, a silicon oxide film are stacked on a semiconductor substrate (not shown). A trench 3 is formed in insulating layer 1 and interlayer insulating layer 2. A barrier layer 4 made of, for example, tantalum (Ta) is formed along a wall surface of trench 3. An interconnection layer 5 made of a copper layer formed by plating (including a seed layer and a plating layer, which will hereinafter be referred to as a plated copper layer) is formed so as to fill trench 3.

On interlayer insulating layer 2, an insulating layer 6 made of, for example, a silicon nitride film, and interlayer insulating layers 7 and 8 each made of, for example, a silicon oxide film are stacked so as to cover interconnection layer 5. A via (hole) 9 reaching interconnection layer 5 is formed in insulating layer 6 and interlayer insulating layer 7. A trench 10 for an interconnection extending above via 9 is formed in interlayer insulating layer 8. Trench 10 and via 9 are in communication with each other.

A barrier layer 11 made of, for example, tantalum nitride (TaN) is formed along wall surfaces of via 9 and trench 10. An interconnection layer 12 made of a plated copper layer is formed so as to fill via 9 and trench 10. Barrier layer 11 is located between the insulating layers (insulation layer 6 and interlayer insulating layers 7 and 8) and interconnection layer 12, and between interconnection layer 5 and interconnection layer 12.

In the present embodiment, in either one or both of interconnection layers 5 and 12, a density of defects such as micro-voids is lower than a defect density in a copper layer formed by typical plating. In the present embodiment, defect densities in interconnection layers 5 and 12 can be reduced by using a defect trapping film in a manufacturing process.

In the following, a manufacturing method in the present embodiment will be described.

With reference to FIG. 2, insulating layer 1 made of, for example, a silicon nitride film, and interlayer insulating layer 2 made of, for example, a silicon oxide film are stacked on the semiconductor substrate (not shown). Trench 3 is formed in insulating layer 1 and interlayer insulating layer 2 by using typical photolithography and etching techniques. Barrier layer 4 made of, for example, tantalum (Ta) is formed so as to cover the wall surface of trench 3 and an upper surface of interlayer insulating layer 2. Plated copper layer 5 is formed so as to fill trench 3 and cover the upper surface of interlayer insulating layer 2. Plated copper layer 5 is formed by forming a copper seed layer and then depositing a copper plating layer by electrolytic plating.

Thereafter, plated copper layer 5 and barrier layer 4 are polished and removed by CMP until the upper surface of interlayer insulating layer 2 is exposed. Thereby, barrier layer 4 and plated copper layer 5 are left only within trench 3, forming interconnection layer 5 made of the plated copper layer.

On interlayer insulating layer 2, insulating layer 6 made of, for example, a silicon nitride film, and interlayer insulating layers 7 and 8 each made of, for example, a silicon oxide film are stacked in order so as to cover interconnection layer 5. By means of typical photolithography and etching techniques, trench 10 for an interconnection is formed in interlayer insulating layer 8, and via 9 is formed in insulating layer 6 and interlayer insulating layer 7. Via 9 is formed from a bottom portion of trench 10 to reach interconnection layer 5, thereby partially exposing a surface of interconnection layer 5.

Barrier layer 11 made of, for example, tantalum nitride (TaN) is formed along the wall surfaces of via 9 and trench 10, an upper surface of interlayer insulating layer 8, the exposed surface of interconnection layer 5, and the like. Plated copper layer 12 is formed so as to fill via 9 and trench 10, and cover the upper surface of interlayer insulating layer 8. Plated copper layer 12 is formed by forming a copper seed layer and then depositing a copper plating layer by electrolytic plating.

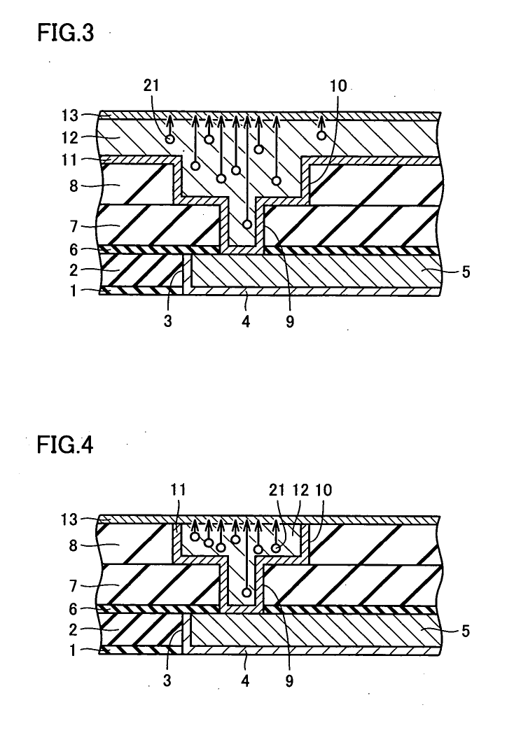

With reference to FIG. 3, defect trapping film 13 is formed so as to contact an upper surface of plated copper layer 12. Defect trapping film 13 is a copper layer formed by, for example, sputtering. Preferably, defect trapping film 13 is made of a material which neither brings an increase in resistance of plated copper layer 12 nor easily causes stress migration, electronic migration, or the like, even if a component in defect trapping film 13 diffuses into plated copper layer 12.

Thereafter, treatment is applied to move defects 21 such as micro-voids in plated copper layer 12 into defect trapping film 13. An example of the treatment to move defects 21 into defect trapping film 13 is annealing, and the annealing is performed, for example, at 100° C. for 90 minutes. By performing such annealing, defects 21 in plated copper layer 12 move into defect trapping film 13 in response to a diffusion effect produced according to a difference between, for example, defect densities of plated copper layer 12 and defect trapping film 13.

After defects 21 in plated copper layer 12 are reduced as described above, CMP is performed to polish and remove defect trapping film 13, plated copper layer 12, and barrier layer 11 until the upper surface of interlayer insulating layer 8 is exposed. Thus, barrier layer 11 and plated copper layer 12 are left only within via 9 and trench 10 as shown in FIG. 1, forming interconnection layer 12 made of the plated copper layer. In this manner, a semiconductor device having an interconnection structure made of a plated copper layer with a reduced defect density is manufactured.

It is to be noted that, although explanation has been given on the case of forming defect trapping film 13 before polishing and partially removing plated copper layer 12, defect trapping film 13 may be formed after polishing and partially removing plated copper layer 12 by means of CMP. For example, after plated copper layer 12 and barrier layer 11 are polished and partially removed from the structure in the state shown in FIG. 2, defect trapping film 13 may be formed so as to contact plated copper layer 12 as shown in FIG. 4. Further, with only plated copper layer 12 polished and partially removed from the structure in the state shown in FIG. 2 and barrier layer 11 left on the upper surface of interlayer insulating layer 8, defect trapping film 13 may be formed so as to contact plated copper layer 12. In either case, treatment for moving defects 21 such as micro-voids in plated copper layer 12 into defect trapping film 13 (such as annealing) is applied after defect trapping film 13 is formed.

By trapping defects 21 with defect trapping film 13 after polishing and partially removing plated copper layer 12 as described above, the defect density in plated copper layer 12 can be reduced more effectively.

Further, trapping of defects 21 with defect trapping film 13 before polishing and partially removing plated copper layer 12 and trapping of defects 21 with defect trapping film 13 after polishing and partially removing plated copper layer 12 may be combined. Thereby, the defect density in plated copper layer 12 can further be reduced.

Although explanation has been given on the case of reducing the defect density in interconnection layer 12, a defect density in interconnection layer 5 may be reduced in a manner similar to the aforementioned manner. Further, the defect density of only either one of interconnection layers 5 and 12 may be reduced in the aforementioned manner, and the defect densities of both of interconnection layers 5 and 12 may be reduced in the aforementioned manner.

According to the present embodiment, the densities of defects 21 such as micro-voids in interconnection layers 5 and 12 can be reduced by defect trapping film 13. Thus, concentration of micro-voids in a portion in proximity to the bottom of the via (a region R1 or R2 in FIG. 1) due to heat stress can be restrained.

Preferably, the defect trapping film in the present embodiment is a film having less defects such as voids and vacancies than the plated copper layer, and made of a material which can fully obtain a diffusion effect produced according to a difference between defect densities of the plated copper layer and the material. In the present embodiment, a copper layer formed by sputtering is used as the defect trapping film, and the copper layer formed by sputtering generally has a defect density lower than that of a plated copper layer. This is because, when depositing a plated copper layer, air inclusion cannot be prevented when immersing a wafer into a plating liquid, and the plating liquid itself contains several types of impurities, introducing a large amount of defects into the plated copper layer. Examples of the impurities contained in the plating liquid include sulfur (S), carbon (C), and the like. These impurities are not contained in the copper layer formed by sputtering.

However, even when forming a copper layer by sputtering, if a negative bias voltage is applied to a wafer to make ions collide with a wafer surface in a depositing process as in, for example, bias sputtering, a number of defects are introduced into the copper layer due to the impact of the collision. Thus, the copper layer formed by bias sputtering does not have a defect trapping function such as required in the present embodiment. Therefore, the copper layer formed by bias sputtering is not suitable as the defect trapping film in the present embodiment.

However, even when a bias voltage is applied to a wafer, if copper deposition by sputtering is performed in high vacuum in a situation that no ions such as argon exist in a treatment chamber (for example, in a situation that argon or the like is used only for plasma generation and exhausted after plasma generation), ions are prevented from colliding with the wafer, eliminating the introduction of a number of defects into the copper layer. Thus, the copper layer formed in this manner is suitable as the defect trapping film in the present embodiment.

As described above, when using a copper layer formed by sputtering as a defect trapping film, a suitable copper layer is the one deposited under a condition such that no ions collide with a wafer (semiconductor device) during sputtering due to a bias voltage applied to the wafer.

### Second Embodiment

In the present embodiment, structures of interconnection layers 5 and 12 are different from those in the first embodiment shown in FIG. 1. Either one or both of interconnection layers 5 and 12 in the present embodiment are plated copper layers to which an inert element is introduced to restrain micro-voids from moving. Therefore, interconnection layers 5 and 12 in the present embodiment do not have to be layers having a defect density reduced by a defect trapping film as in the first embodiment.

Examples of the inert element include helium (He), neon (Ne), argon (Ar), krypton (Kr), xenon (Xe), and radon (Rn). Although any element among them may be introduced, argon is particularly preferable.

It is to be noted that, since the structure of the present embodiment is otherwise substantially the same as that of the first embodiment, like reference characters indicate like components, and description thereof will not be repeated.

A manufacturing method in the present embodiment will now be described.

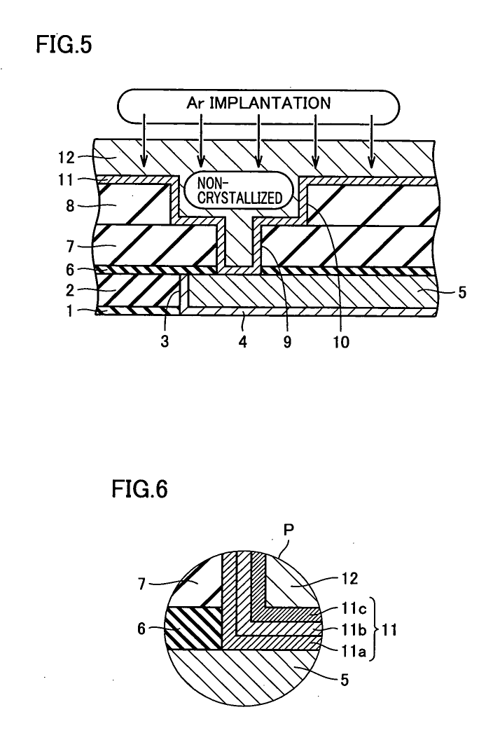

The manufacturing method in the present embodiment follows a process similar to that in the first embodiment up to the FIG. 2 step. Then, with reference to FIG. 5, an inert element (for example, argon) is implanted into plated copper layer 12, thereby making part or all of plated copper layer 12 amorphous. That is, bonding of copper atoms is cut by the implantation of the inert element, and the inert element itself is a chemically stable substance and does not bind to copper, which results in plated copper layer 12 in an amorphous state.

Thereafter, annealing is performed, for example, at 100° C. and for 90 minutes. By this annealing, plated copper layer 12 in an amorphous state is crystallized and becomes crystalline. Thereby, film quality of plated copper layer 12 is improved as will be described later, restraining voids in plated copper layer 12 from moving.

After the film quality of plated copper layer 12 is improved as described above, CMP is performed to polish and remove plated copper layer 12 and barrier layer 11 until the upper surface of interlayer insulating layer 8 is exposed. Thereby, barrier layer 11 and plated copper layer 12 are left only within via 9 and trench 10 as shown in FIG. 1, forming interconnection layer 12 made of the plated copper layer. In this manner, a semiconductor device having an interconnection structure made of a copper layer in which voids are retrained from moving is manufactured.

It is to be noted that, although explanation has been given on the case of performing annealing after implanting the inert element into plated copper layer 12, annealing may be performed after implanting an inert element into plated copper layer 5. In this case, voids in plated copper layer 5 can be restrained from moving as will be described later. Further, annealing may be performed after implanting an inert element into both of plated copper layers 5 and 12. In this case, voids in both of plated copper layers 5 and 12 can be restrained from moving as will be described later.

According to the present embodiment, plated copper layers 5 and 12 are once caused to be amorphous by the implantation of the inert element, and then caused to be crystalline by annealing. Copper has better fluidity in an amorphous state than in a crystalline state. Thus, when annealing is performed under the same condition, growth of copper crystal grains can be promoted and vacancies can be reduced more in an amorphous state than in a crystalline state. Further, since the size of copper crystal grains can be increased by the promotion of growth of the copper crystal grains, boundaries between the crystal grains (triple points) in which voids are apt to occur can be reduced, and an interval between the triple points can be increased. Thereby, voids in plated copper layers 5 and 12 can be retrained from moving. Therefore, concentration of micro-voids in the portion in proximity to the bottom of the via (region R1 or R2 in FIG. 1) due to heat stress can be restrained.

### Third Embodiment

With reference to FIG. 6, the structure of the present embodiment is different from that of the first embodiment in terms of the structure of barrier layer 11. Barrier layer 11 in the present embodiment has a tantalum nitride layer 11b, and has a structure that tantalum nitride layer 11b is sandwiched by layers 11a and 11c having a better adhesion property to copper than tantalum nitride layer 11b such that tantalum nitride layer 11b contacts neither interconnection layer 5 nor interconnection layer 12.

Barrier layer 11 has a structure in which three layers of, for example, tantalum layer 11a, tantalum nitride layer 11b, and tantalum layer 11c are stacked in order, that is, a multi-layer structure in which tantalum nitride layer 11b is sandwiched by tantalum layers 11a and 11c. Tantalum layer 11a, tantalum nitride layer 11b, and tantalum layer 11c are formed along the wall surfaces of via 9 and trench 10, and located between interconnection layer 12 and the insulating layers (insulation layer 6 and interlayer insulating layers 7 and 8), and between interconnection layer 5 and interconnection layer 12.

Layers 11a and 11c sandwiching tantalum nitride layer 11b are not limited to tantalum layers, and may be any kind of layers having a better adhesion property to copper than tantalum nitride layer 11b. Layers 11a and 11c may be titanium nitride (TiN) layers, titanium silicide (TiSi₂) layers, tungsten nitride (WN) layers, or the like. Further, layers 11a and 11c underlying and overlying, respectively, tantalum nitride layer 11b may be made of respective different materials.

Interconnection layers 5 and 12 in the present embodiment do not have to be layers having a defect density reduced by a defect trapping film as in the first embodiment.

It is to be noted that, since the structure of the present embodiment is otherwise substantially the same as that of the first embodiment, like reference characters indicate like components, and description thereof will not be repeated.

A manufacturing method in the present embodiment will now be described.

With reference to FIG. 2, in the manufacturing method of the present embodiment, insulating layer 1, interlayer insulating layer 2, trench 3, barrier layer 4, interconnection layer 5, insulating layer 6, interlayer insulating layers 7 and 8, via 9, and trench 10 are formed by a method similar to that of the first embodiment.

Thereafter, three layers of, for example, tantalum layer 11a, tantalum nitride layer 11b, and tantalum layer 11c are stacked in order along the wall surfaces of via 9 and trench 10, the upper surface of interlayer insulating layer 8, the exposed surface of interconnection layer 5, and the like, forming barrier layer 11 having a multi-layer structure of the three layers.

Plated copper layer 12 is formed so as to fill via 9 and trench 10, and cover the upper surface of interlayer insulating layer 8. Plated copper layer 12 is formed by forming a copper seed layer and then depositing a copper plating layer by electrolytic plating.

Thereafter, CMP is performed to polish and remove plated copper layer 12 and barrier layer 11 until the upper surface of interlayer insulating layer 8 is exposed. Thus, barrier layer 11 and plated copper layer 12 are left only within via 9 and trench 10 as shown in FIG. 1, forming interconnection layer 12 made of the plated copper layer. In this manner, a semiconductor device having an interconnection structure of a copper layer is manufactured.

According to the present embodiment, barrier layer 11 located between interconnection layer 12 and the insulating layers (insulation layer 6 and interlayer insulating layers 7 and 8) has tantalum nitride layer 11b with a high barrier property. Thus, copper in interconnection layer 12 can effectively be prevented from diffusing into the insulating layers.

In addition, tantalum nitride layer 11b of barrier layer 11 contacts neither interconnection layer 5 nor interconnection layer 12. Thus, bonding of copper and tantalum nitride, which is a structure having a weak adhesion property and a high rate of occurrence of voids, can be prevented. That is, since a copper layer and a tantalum nitride layer have a poor adhesion property therebetween, a minute gap occurs between these layers and is identified as a void. However, such direct contact between a copper layer and a tantalum nitride layer are prevented in the present embodiment. Further, since a tantalum layer is a material having a property to adhere to a copper layer stronger than a tantalum nitride layer, a void hardly occurs between the tantalum layer and the copper layer. Therefore, concentration of micro-voids in proximity to a contact portion between interconnection layer 5 and barrier layer 11 and in proximity to a contact portion between interconnection layer 12 and barrier layer 11 due to heat stress can be restrained.

It is to be noted that barrier layer 4 may have a structure similar to that of barrier layer 11.

### Fourth Embodiment

The structure of the present embodiment is different from that of the first embodiment shown in FIG. 1 in terms of the structures of interconnection layers 5 and 12. Either one or both of interconnection layers 5 and 12 in the present embodiment is/are a plated copper layer/layers into which an element in group 8 of the periodic table is introduced to fill vacancies in interconnection layers 5 and 12. Therefore, interconnection layers 5 and 12 in the present embodiment do not have to be layers having a defect density reduced by a defect trapping film as in the first embodiment.

Examples of the element in group 8 of the periodic table include iron (Fe), cobalt (Co), nickel (Ni), ruthenium (Ru), rhodium (Rh), palladium (Pd), osmium (Os), iridium (Ir), and platinum (Pt). Any element among them may be introduced.

Further, the concentration of the element in group 8 in interconnection layers 5 and 12 is preferably 5% by mass or less, more preferably 0.5% by mass. When the concentration of the element in group 8 in interconnection layers 5 and 12 exceeds 5% by mass, negative effects such as an increase in the resistance of interconnection layers 5 and 12 become noticeable.

It is to be noted that, since the structure of the present embodiment is otherwise substantially the same as that of the first embodiment, like reference characters indicate like components, and description thereof will not be repeated.

A manufacturing method in the present embodiment will now be described.

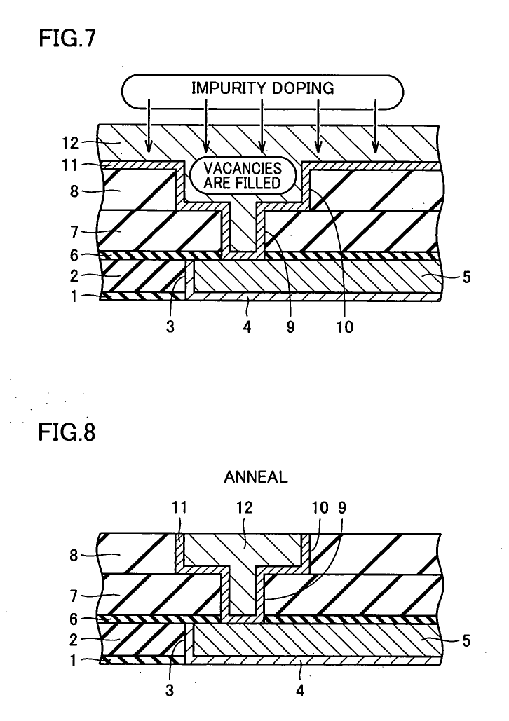

The manufacturing method in the present embodiment follows a process similar to that in the first embodiment up to the FIG. 2 step. Then, with reference to FIG. 7, an element in group 8 of the periodic table is introduced into plated copper layer 12, for example by the following methods:

Method 1: Plated copper layer 12 is formed, a layer containing an element in group 8 is deposited over plated copper layer 12, and the element in group 8 is diffused from the layer into plated copper layer 12.

Method 2: A copper seed layer is formed by sputtering using a target containing an element in group 8 in advance. Then, electrolytic plating is performed using the seed layer containing the element in group 8 to form plated copper layer 12 so as to contain the element in group 8 from when it is deposited.

Method 3: An element in group 8 is added into a plating liquid, and plated copper layer 12 is formed by plating. Thereby, plated copper layer 12 is formed so as to contain the element in group 8 from when it is deposited.

The element in group 8 that has been introduced into plated copper layer 12 fills vacancies in plated copper layer 12. Thereafter, annealing is performed, promoting a phenomenon that the element in group 8 fills the vacancies.

After the vacancies in plated copper layer 12 are filled as described above, CMP is performed to polish and remove plated copper layer 12 and barrier layer 11 until the upper surface of interlayer insulating layer 8 is exposed. Thus, barrier layer 11 and plated copper layer 12 are left only within via 9 and trench 10 as shown in FIG. 1, forming interconnection layer 12 made of the plated copper layer. In this manner, a semiconductor device having an interconnection structure made of a copper layer with reduced vacancies is manufactured.

It is to be noted that, although explanation has been given on the case of introducing an element in group 8 into plated copper layer 12, the element in group 8 may be introduced into plated copper layer 5. Thereby, vacancies in plated copper layer 5 can be filled. Further, the element in group 8 may be introduced into both of plated copper layers 5 and 12. In this case, vacancies in both of plated copper layers 5 and 12 can be filled.

According to the present embodiment, an element in group 8 is introduced into plated copper layers 5 and 12. The diffusion coefficient of an element in group 8 is greater than that of copper. For example, as for diffusion coefficients in grain boundary diffusion when gold (Au) is a matrix, the diffusion coefficient of nickel is 4×10⁻⁵ cm²/sec. and that of chromium is 1×10⁻³ cm²/sec., whereas that of copper is 1×10⁻⁵ cm²/sec. Since a greater diffusion coefficient results in a higher probability of contacting vacancies, vacancies can effectively be filled with an element in group 8. Therefore, concentration of micro-voids in the portion in proximity to the bottom of the via (region R1 or R2 in FIG. 1) due to heat stress can be restrained.

In the present embodiment, a requirement for a material filling vacancies is that the material has a diffusion coefficient greater than that of copper. Further, it is preferable that the material causes less increase in the resistance and less deterioration in the reliability of a copper layer when added to the copper layer.

### Fifthe Embodiment

The structure of the present embodiment is different from that of the first embodiment shown in FIG. 1 in terms of the structures of interconnection layers 5 and 12. Either one or both of interconnection layers 5 and 12 in the present embodiment has/have stabilized film quality by undergoing thermal treatment (such as annealing) after the plated copper layers constituting the interconnection layer(s) are polished and partially removed. Therefore, interconnection layers 5 and 12 in the present embodiment do not have to be layers having a defect density reduced by a defect trapping film as in the first embodiment.

It is to be noted that, since the structure of the present embodiment is otherwise substantially the same as that of the first embodiment, like reference characters indicate like components, and description thereof will not be repeated.

A manufacturing method in the present embodiment will now be described.

The manufacturing method in the present embodiment follows a process similar to that in the first embodiment up to the FIG. 2 step. After plated copper layer 12 is formed by electrolytic plating in this manner, CMP is performed to polish and remove plated copper layer 12 and barrier layer 11 until the upper surface of interlayer insulating layer 8 is exposed, without annealing.

With reference to FIG. 8, by the foregoing polishing and removal, barrier layer 11 and plated copper layer 12 are left only within via 9 and trench 10 (that is, within a concave portion), forming interconnection layer 12 made of the plated copper layer. Then, with a surface of interconnection layer 12 exposed, thermal treatment for stabilizing the film quality of interconnection layer 12, such as annealing, is performed. A preferable annealing condition is to provide heat at a temperature of not less than 300° C. nor more than 500° C. for less than 20 minutes, or to provide heat at a temperature of not less than 80° C. nor more than 200° C. for not less than 30 minutes nor more than 1.5 hours. If a temperature is higher or a treatment time is longer than the foregoing conditions, a number of voids would occur. If a temperature is lower or a treatment time is shorter than the foregoing conditions, an annealing effect cannot be fully obtained.

In this manner, a semiconductor device having an interconnection structure made of a copper layer in which voids are retrained from moving is manufactured.

It is to be noted that, although explanation has been given on the case of performing thermal treatment after polishing and partially removing both of plated copper layer 12 and barrier layer 11, thermal treatment may be performed with barrier layer 11 left on the upper surface of interlayer insulating layer 8, by stopping the polishing and partial removal of plated copper layer 12 when a surface of barrier layer 11 is exposed.

Further, although explanation has been given on plated copper layer 12, plated copper layer 5 may also undergo thermal treatment for stabilizing the film quality of plated copper layer 5 after being polished and partially removed. Furthermore, plated copper layers 5 and 12 may both undergo thermal treatment for stabilizing the film quality of the plated copper layers after being polished and partially removed.

A copper layer formed by electrolytic plating has small crystal grains, and when it is left to stand, crystal grain growth occurs even at room temperature. Since the electrical resistance of the copper layer varies according to the crystal grain growth, it lacks stability. Therefore, to stabilize the copper layer, it is necessary to provide thermal treatment such as annealing to the copper layer.

According to the present embodiment, thermal treatment for stabilizing film quality is provided after plated copper layers 5 and 12 are polished and partially removed. Thus, heat conduction efficiency of plated copper layers 5 and 12 during thermal treatment is improved, because plated copper layers 5 and 12 have smaller volumes by being polished and partially removed, compared with the case that thermal treatment is provided before plated copper layers 5 and 12 are polished and partially removed. Thereby, portions in proximity to the bottom of the via in plated copper layers 5 and 12 can efficiently be heated, allowing effective and efficient stabilization of the film quality of the portions. In addition, since the volume of the (plated) copper layer is reduced by the polishing and partial removal, an absolute number of vacancies in the (plated) copper layer can also be decreased by the amount of the reduced volume.

By providing thermal treatment for stabilizing film quality after the polishing and partial removal of the plated copper layer, the plated copper layer can be stabilized effectively and efficiently, and the absolute number of vacancies in the plated copper layer can also be decreased. Thus, concentration of micro-voids in the portion in proximity to the bottom of the via (region R1 or R2 in FIG. 1) due to heat stress can be restrained.

It is to be noted that the structures or manufacturing processes in the foregoing first to fifth embodiments may be combined as appropriate.

Further, in the present specification, a copper layer means a layer made of a material containing copper as a main component, and includes a layer made of copper containing an unavoidable impurity, a copper alloy layer, and the like.

In addition, a plated copper layer is different from a copper layer formed by sputtering in that the plated copper layer contains impurities such as chlorine (Cl), carbon (C), sulfur (S), or the like included in a plating chemical liquid.

In the following, the reason for depositing a copper layer by plating will be described.

Copper is a material difficult to be used for patterning by dry etching. Thus, to form a copper interconnection pattern, a technique is used in which a copper layer is formed so as to fill an interconnection trench formed on a surface of an insulating layer, and then CMP or the like is performed to polish and remove the copper layer to be left only within the interconnection trench. Here, when filling the interconnection trench with the copper layer, there is a method in which the copper layer is deposited by CVD (Chemical Vapor Deposition) or sputtering to fill the interconnection trench. However, with this method, an overhang of the copper layer may occur at a stepped portion formed by the interconnection trench and the copper layer may not completely fill the interconnection trench. Although the copper layer deposited by this method may be flown to fill the interconnection trench without any gap, the copper layer would then have to be heated to a temperature as high as 1000° C. and more to be flown, which arises a concern about an adverse effect on a device.

Therefore, to fill the interconnection trench without any gap by a simple method, the copper layer is deposited by plating.

Further, although explanation has been given on a plated copper layer, the present invention can also be applied to a copper layer having a defect density similar to that of the plated copper layer.

Although the present invention has been described and illustrated in detail, it is dearly understood that the same is by way of illustration and example only and is not to be taken by way of limitation, the spirit and scope of the present invention being limited only by the terms of the appended claims.

What is claimed is:

1. A semiconductor device, comprising:
a first copper layer;
an insulating layer formed on said first copper layer and having a via reaching said first copper layer;
a second copper layer electrically connected to said first copper layer through said via; and
a barrier layer located between said second copper layer and said insulating layer, and between said first copper layer and said second copper layer, said barrier layer having a structure with a tantalum nitride layer sandwiched by layers having a better adhesive property to copper than said tantalum nitride layer.

2. The semiconductor device according to claim 1, wherein said barrier layer has a multi-layer structure with said tantalum nitride layer sandwiched by tantalum layers.

3. A semiconductor device, comprising:
a first copper layer;
an insulating layer formed on said first copper layer and having a via reaching said first copper layer; and
a second copper layer electrically connected to said first copper layer through said via, at least either one of said first and second copper layers containing an inert element.

4. The semiconductor device according to claim 3, wherein said inert element is argon.

5. A semiconductor device, comprising:
a first copper layer;
an insulating layer formed on said first copper layer and having a via reaching said first copper layer; and
a second copper layer electrically connected to said first copper layer through said via, at least either one of said first and second copper layers containing an element in group 8 of a periodic table.
